(19) United States
(12) Patent Application Publication
(10) Pub. No.: US 2025/0320439 A1
(43) Pub. Date: Oct. 16, 2025

(54) CLEANING COMPOSITION AND METHOD OF FORMING PHOTORESIST PATTERN USING THE SAME

(71) Applicant: DONGWOO FINE-CHEM CO., LTD., Jeollabuk-do (KR)

(72) Inventors: BAEK HYUN CHO, Jeollabuk-do (KR); GI JIN KWUN, Jeollabuk-do (KR); HYUNG SUB CHOI, Jeollabuk-do (KR)

(21) Appl. No.: 19/077,265

(22) Filed: Mar. 12, 2025

(30) Foreign Application Priority Data
Apr. 12, 2024 (KR) 10-2024-0049181

(51) Int. Cl. C11D 7/50; B08B 3/08; C11D 7/20; G03F 7/40; H01L 21/02

(52) U.S. Cl. CPC C11D 7/5022; B08B 3/08; C11D 7/20; G03F 7/40; H01L 21/0206

(57) ABSTRACT

A cleaning composition includes an alcohol solvent and zeolite. The content of the zeolite is greater than 0 and equal to or less than 1 ppb based on the total weight of the cleaning composition. The cleaning composition may exhibit improved temporal stability and improved cleaning performance of semiconductor substrate residues.

### CROSS REFERENCE TO RELATED APPLICATION AND CLAIM OF PRIORITY

This application claims the benefit under 35 USC § 119 of Korean Patent Application No. 10-2024-0049181 filed on Apr. 12, 2024 in the Korean Intellectual Property Office, the entire disclosure of which is incorporated herein by reference for all purposes.

### BACKGROUND

### 1. Field of the Invention

The present invention relates to a cleaning composition and a method of forming a photoresist pattern using the same.

### 2. Description of the Related Art

A composition including an alcohol solvent may be used for cleaning electronic devices such as a semiconductor device or removing photoresist residues in photolithography during the semiconductor device manufacturing process.

For example, photoresist may be applied to a substrate, exposed to light of a specific wavelength, and then subjected to dry or wet etching, to manufacture a semiconductor device or a high-resolution flat panel display having fine wiring patterns formed on the substrate.

After forming the photoresist pattern through exposure and development processes, any residue remaining on the semiconductor substrate should be removed using a cleaning solution. However, if micron-sized impurities are present in the cleaning solution, the impurities may remain on the surface of the semiconductor device, potentially causing defects.

The impurities may be inevitably introduced into the cleaning solution during the manufacturing process or may be formed as a result of side reactions between components during storage. Therefore, it is preferable to suppress a generation of impurities, even when the cleaning solution is stored for a long period of time.

### SUMMARY

An object of the present invention is to provide a cleaning composition having improved temporal stability and cleaning power.

Another object of the present invention is to provide a method of forming a photoresist pattern using the cleaning composition.

To achieve the above objects, the following technical solutions are adopted in the present invention.

1. A cleaning composition including: an alcohol solvent; and zeolite, wherein a content of the zeolite is greater than 0 and 1 ppb or less based on a total weight of the composition.

2. The cleaning composition according to claim 1, wherein the content of the zeolite is 0.1 ppt to 0.5 ppb based on the total weight of the composition.

3. The cleaning composition according to claim 1, wherein the zeolite includes type A zeolite, type X zeolite or type Y zeolite.

4. The cleaning composition according to claim 1, wherein a water content in the composition is 1 ppm to 30 ppm based on the total weight of the composition.

5. The cleaning composition according to claim 1, wherein the alcohol solvent includes an alcohol having 2 to 5 carbon atoms.

6. The cleaning composition according to claim 1, wherein the alcohol solvent includes at least one selected from the group consisting of ethanol, 1-propanol, 2-propanol, 1-butanol and 1-pentanol.

7. The cleaning composition according to claim 1, wherein the alcohol solvent includes 2-propanol, and further includes at least one selected from the group consisting of ethanol, 1-propanol, 1-butanol and 1-pentanol.

8. The cleaning composition according to claim 7, wherein a content of 2-propanol, based on the total weight of the composition, is 99% by weight or more and less than 100% by weight.

9. The cleaning composition according to claim 1, wherein the composition satisfies Equation 1 below:

$$C \leq ( X / Y ) - 1 \leq D \qquad [ Equation 1 ]$$

(in Equation 1 above, X is a total content of aldehyde compound and ketone compound, based on the total weight of the composition, measured after storing the cleaning composition at 60° C. for 90 days, Y is the total content of aldehyde compound and ketone compound, based on the total weight of the composition, measured before the storage, C is greater than 0 and 0.05 or less, and D is 0.07 to 0.2).

10. The cleaning composition according to claim 9, wherein in Equation 1 above, C is 0.03, and D is 0.1.

11. A method of forming a photoresist pattern including: forming a photoresist film on a substrate; partially removing the photoresist film to form a photoresist pattern; and cleaning the substrate, on which the photoresist pattern is formed, using the cleaning composition according to the above 1.

The cleaning composition according to the embodiments of the present invention may suppress the generation of impurities even after prolonged storage. Accordingly, the temporal stability of the cleaning composition may be enhanced, and the cleaning performance of a semiconductor substrate may also be improved.

Therefore, during manufacturing electronic devices such as a semiconductor or display, the formation of impurities on the surface of the electronic device may be prevented, and the occurrence of defects may be suppressed, thereby improving the production yield of the electronic device.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 4 are schematic cross-sectional views for describing a method of forming a pattern according to exemplary embodiments.

### DETAILED DESCRIPTION

The embodiments of the present invention provide a cleaning composition including an alcohol solvent and zeolite. Accordingly, the temporal stability and purity of the cleaning composition may be improved. In addition, a method of forming a photoresist pattern using the cleaning composition is provided.

As used herein, the abbreviation “ppb” means “parts-per-billion (10⁻⁹),” and the abbreviation “ppt” means “parts-per-trillion (10⁻¹²),” wherein the ppb and ppt may be based on the weight.

Hereinafter, embodiments of the present invention will be described in detail.

### <Cleaning Composition>

The cleaning composition (hereinafter, may be abbreviated as a composition) according to exemplary embodiments may include an alcohol solvent and zeolite.

The alcohol solvent may remove, for example, process residues such as undeveloped photoresist or residual developer existing on a semiconductor substrate. For example, organic and inorganic residues remaining between photoresist patterns after exposure and development may be effectively removed from the semiconductor substrate.

In some embodiments, the alcohol solvent may include an alcohol having 2 to 5 carbon atoms.

For example, the alcohol solvent may include at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol, and 2,2-dimethyl-1-propanol.

For example, methanol has high volatility thereby causing a deterioration in the cleaning power and stability, and an alcohol having greater than 5 carbon atoms may remain on a surface of the semiconductor substrate after cleaning. Therefore, when the alcohol solvent includes an alcohol having 2 to 5 carbon atoms, an occurrence of defects during manufacturing a semiconductor device may be reduced.

According to exemplary embodiments, the alcohol solvent may be obtained by refining a crude oil. The purity of the alcohol solvent may be improved through the purification process.

For example, as the crude oil before purification, 2-propanol derived from fossil resources such as coal, oil, and natural gas, etc. may be used, and 2-propanol (bio-2-propanol) derived from a biomass source may be used.

Examples of bio-2-propanol may include: 2-propanol obtained using bacteria that produce 2-propanol from a biomass raw material (see International Patent Publication No. 2009/008377); 2-propanol obtained by hydrating propylene acquired using biomethanol; 2-propanol obtained by reducing acetone acquired using bioethanol; and 2-propanol obtained by hydrating propylene acquired using bioethanol.

In some embodiments, the alcohol solvent may include a secondary alcohol. For example, examples of the secondary alcohol may include 2-propanol, 2-butanol, 2-pentanol, 3-pentanol, or 3-methyl-2-butanol, and preferably 2-propanol.

In some embodiments, the alcohol solvent may include at least one selected from the group consisting of ethanol, 1-propanol, 2-propanol, 1-butanol and 1-pentanol.

In some embodiments, the alcohol solvent includes 2-propanol, and may include an alcohol solvent different from 2-propanol. For example, the alcohol solvent may include 2-propanol and at least one selected from the group consisting of ethanol, 1-propanol, 1-butanol and 1-pentanol.

For example, alcohols containing 2 or 3 carbon atoms may have a low boiling point, thereby preventing them from remaining on the surface of the semiconductor substrate after cleaning. Accordingly, the yield of the manufactured semiconductor device may be increased.

In some embodiments, the alcohol solvent may include an alcohol having a boiling point of 110° C. or lower. For example, the alcohol having a boiling point of 110° C. or lower may include ethanol, 1-propanol, 2-propanol, 2-butanol, isobutanol, tert-butanol, or tert-amyl alcohol.

For example, alcohols having a boiling point of 110° C. or lower may be vaporized at a lower temperature, thereby preventing them from remaining on the surface of the semiconductor substrate after cleaning.

In some embodiments, the alcohol solvent may have a vapor pressure of 0.5 kPa or more at 25° C. For example, an alcohol having a vapor pressure of 0.5 kPa or more at 25° C. may include ethanol, 1-propanol, 2-propanol, 1-butanol, 2-butanol, isobutanol, tert-butanol, 2-pentanol, 3-pentanol, tert-amyl alcohol or 2,2-dimethyl-1-propanol.

For example, alcohols having a vapor pressure of 0.5 kPa or more at 25° C. may be more easily vaporized, thereby preventing them from remaining on the surface of the semiconductor substrate after cleaning.

According to exemplary embodiments, a content of the alcohol solvent, based on a total weight of the composition, may be 99% by weight (“wt %”) to less than 100 wt %. In some embodiments, the content of 2-propanol, based on the total weight of the composition, may be 99 wt % or more and less than 100 wt %. In one embodiment, the content of 2-propanol, based on the total weight of the composition, may be 99.9 wt % or more, 99.95 wt % or more, or 99.99 wt % and less than 100 wt % or more.

In some embodiments, the cleaning composition may include 2-propanol and an alcohol solvent different from 2-propanol as the balance excluding the content of the zeolite. For example, the cleaning composition includes zeolite in the amount to be described below and 2-propanol in the above-described amount, and may include the balance of an alcohol solvent different from 2-propanol.

The term “balance” as used herein refers to a variable amount that can be changed depending on the addition of other components.

When the composition is stored for a long period of time, the alcohol solvent may undergo a natural oxidation reaction, leading to the formation of impurities such as aldehydes and ketones. These impurities may aggregate into large particles having a large molecular weight and a micron-scale size, potentially remaining on the surface of the semiconductor substrate after cleaning.

The composition may include a temporal inhibitor, and the temporal inhibitor may inhibit the oxidation of the alcohol solvent, thereby preventing the formation of aldehydes and ketones. Accordingly, the temporal stability of the cleaning composition may be enhanced, and high purity may be ensured.

The composition may include water. The content of water (water content) in the composition may be 1 ppm to 30 ppm. According to some embodiments, the water content of the composition may be 3 ppm to 20 ppm, or 5 ppm to 15 ppm. Within the above range, when the composition is used, the formation of residues or water marks on the surface of the object to be cleaned may be prevented.

For example, the temporal inhibitor may include zeolite, and the zeolite may be in the form of fine particle dispersion.

According to exemplary embodiments, the zeolite may include silicon and aluminum. According to some embodiments, the zeolite compound may include type A zeolite, type X zeolite, or type Y zeolite.

The type A zeolite may have an atomic ratio of silicon to aluminum (Si/Al) of about 1. The type X zeolite may have a Si/Al ratio of 1 to 1.5. The type Y zeolite may have a Si/Al ratio of 1.5 or more.

According to one embodiment, the zeolite may include type Y zeolite. The type Y zeolite may be, for example, zeolite with CAS No. 1318 Feb. 1.

According to one embodiment, the zeolite may include a compound represented by Formula 1 below.

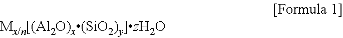

(in Formula 1, M is a metal, x and y are arbitrary positive numbers, z is the number of hydrated water molecules, and n is a charge of a metal cation)

The zeolite may suppress side reactions through moisture absorption. Accordingly, the temporal stability of the cleaning composition may be improved.

According to exemplary embodiments, the composition may be prepared by introducing the zeolite into the alcohol solvent. According to one embodiment, the zeolite may be included and remain during the process of preparing the alcohol solvent.

In exemplary embodiments, a content of the zeolite, based on the total weight of the composition, is greater than 0 and less than 1 ppb. According to some embodiments, the content of the zeolite, based on the total weight of the composition, may be 0.1 ppt to 0.5 ppb or 0.1 ppt to 10 ppt.

Within the above range, the temporal stability of the composition may be improved, and the residue cleaning performance of the composition for the semiconductor substrate may be improved.

If the composition does not include zeolite, the formation of aldehydes and/or ketones due to the decomposition of the alcohol solvent may rapidly increase during long-term storage of the composition. Accordingly, a uniform production speed in the semiconductor manufacturing process using the composition may not be ensured, and the cleaning power of the composition may also reduce, thereby deteriorating the quality of the semiconductor product.

If the composition includes zeolite in an amount exceeding 1 ppb, residues, etc. may be generated after cleaning due to the metal components contained in the zeolite. In addition, an excessive amount of zeolite may act as a decomposition reaction catalyst of an alcohol solvent, for example, 2-propanol. Thereby, the content of acetal compounds formed by a decomposition reaction may increase, leading to a reduction in the temporal stability of the composition.

According to exemplary embodiments, the cleaning composition may satisfy Equation 1.

$$C \leq ( X / Y ) - 1 \leq D \qquad [ Equation 1 ]$$

In Equation 1 above, X may be a total content of aldehyde compound and ketone compound, based on the total weight of the composition, measured after storing the cleaning composition at 60° C. for 90 days, and Y may be the total content of aldehyde compound and ketone compound, based on the total weight of the composition, measured before storage.

In Equation 1 above, C may be greater than 0 and 0.05 or less, and D may be 0.07 to 0.2.

A change rate of the aldehyde compound and ketone compound contents before and after high-temperature storage of the composition may be, for example, 20% or less, 15% or less, 10% or less, or 7% or less.

The change rate of the aldehyde compound and ketone compound contents before and after high-temperature storage of the composition may be, for example, greater than 0, 0.01% or more, 0.02% or more, or 0.03% or more.

For example, in Equation 1, D may be 0.2, 0.15, 0.1, or 0.07, and C may be 0.01, 0.02, or 0.03.

Within the above range, the cleaning composition may exhibit improved temporal stability and its long-term storage stability may be enhanced.

The aldehyde compound and ketone compound may be trace impurities formed by natural oxidation of the alcohol solvent. The composition may exhibit improved temporal stability, thereby suppressing an increase in impurities including aldehyde compound and ketone compound, even during long-term storage.

In one embodiment, in Equation 1, X may be the total content of acetaldehyde and acetone, based on the total weight of the composition, measured after storing the cleaning composition at 60° C. for 90 days, and Y may be the total content of acetaldehyde and acetone, based on the total weight of the composition, measured before storage.

In Equation 1 above, X and Y are greater than 0, X may be 2600 ppb or less, 2500 ppb or less, 2400 ppb or less, or 2300 ppb or less, and Y may be 2300 ppb or less, or 2200 ppb or less.

### <Method of Forming a Photoresist Pattern>

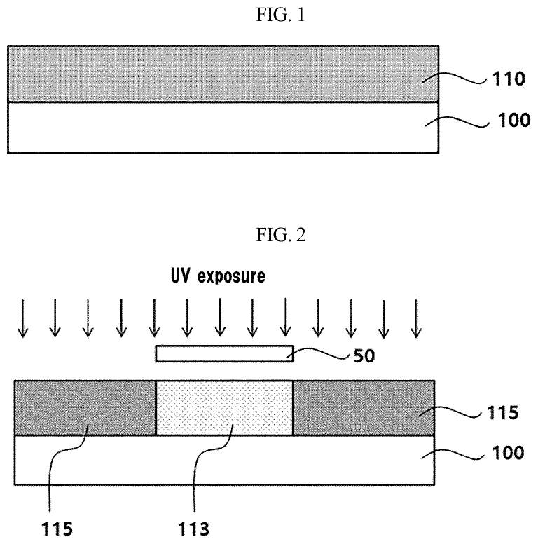

FIGS. 1 to 4 are schematic cross-sectional views for describing a method of forming a pattern according to exemplary embodiments. For example, FIGS. 1 to 4 illustrate and describe a pattern formation process using a negative photoresist.

However, the cleaning composition according to the exemplary embodiments is not limited to the processes shown in FIGS. 1 to 4, and may also be utilized in a pattern formation process using a positive photoresist.

Referring to FIG. 1, a photoresist material may be applied to a substrate 100 to form a photoresist film 110.

The substrate 100 may include a semiconductor material such as single-crystal silicon or single-crystal germanium, and may also be formed to include polysilicon.

In some embodiments, after forming the photoresist film 110, a soft baking process may be performed. Accordingly, an organic solvent that can be included in the photoresist film 110 may be evaporated.

Referring to FIG. 2, a non-exposed part 113 and an exposed part 115 may be formed on the substrate 100 through an exposure process. The exposure process may be performed using a light source (e.g., EUV light source) and an exposure mask 50.

The photoresist film 110 may be irradiated with light (e.g., EUV) passing through the exposure mask 50. Thereby, the photoresist film 110 may be patterned to have the non-exposed part 113 and the exposed part 115.

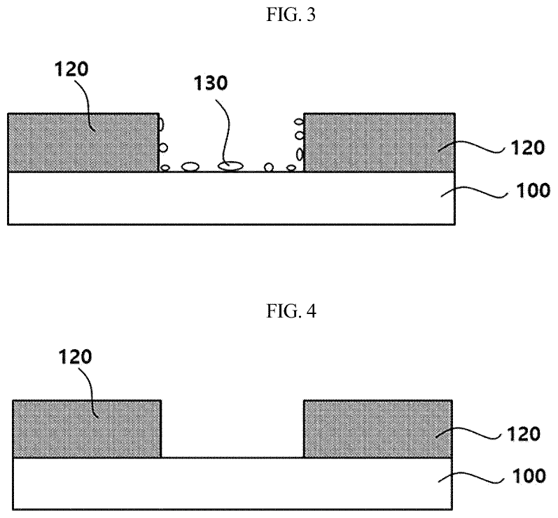

Referring to FIG. 3, a photoresist pattern 120 may be formed on the substrate 100 through a development process. For example, the photoresist film 110 may be partially removed to form a photoresist pattern. Specifically, the photoresist patterns 120 consisting of the exposed parts 115 may be formed by removing the non-exposed parts 113 from the substrate 100 using a developer. The developer may be an aqueous solution of tetramethylammonium hydroxide (TMAH).

FIG. 3 illustrates and describes a pattern formation process using a negative photoresist, but it is not limited thereto. For example, a pattern formation process using a positive photoresist may be alternatively performed. In this case, the exposed part 115 may be removed to form a photoresist pattern consisting of the non-exposed part 113.

In some embodiments, a post-baking process may be further performed after the exposure process or after the development process.

After the pattern formation process, development residues 130 may remain on the substrate 100. The development residues 130 may include undeveloped photoresist or developer residues. If the development residues 130 remain on the substrate 100 or the photoresist pattern 120, defects may occur during the semiconductor device manufacturing process.

Referring to FIG. 4, the substrate 100, on which the photoresist pattern 120 is formed, may be cleaned using the cleaning composition according to exemplary embodiments. Specifically, the above-described cleaning composition according to the exemplary embodiments may be applied to or used to immerse the substrate 100. Accordingly, the development residues 130 formed on the substrate 100 or the photoresist pattern 120 may be removed.

The cleaning step may be performed by applying the above-described cleaning composition according to the exemplary embodiments to the substrate 100 under commonly known cleaning conditions.

In some embodiments, the temperature during the cleaning may be generally 25° C. to 70° C., and preferably 25° C. to 50° C. A residence time of the substrate 100 when immersed in the cleaning composition may be about 5 seconds to 10 minutes, and preferably 10 seconds to 5 minutes.

In some embodiments, the cleaning step may involve a first cleaning to remove the development residues with deionized water, followed by a second cleaning using the above-described cleaning composition according to the exemplary embodiments.

As described above, the cleaning composition includes the alcohol solvent and the organometallic compound in a predetermined content, thereby improving the temporal stability and purity. Accordingly, defect occurrence in the semiconductor device may be suppressed, leading to an improved production yield.

The cleaning composition according to the exemplary embodiments may be used in a cleaning process for electronic devices such a semiconductor or display other than in the pattern formation process using the photoresist, and may be applicable in other fields where the alcohol solvent is used.

Hereinafter, experimental examples including specific examples and comparative examples are proposed to facilitate understanding of the present invention. However, the following examples are only given for illustrating the present invention and are not intended to limit the appended claims. It will be apparent those skilled in the art that various alterations and modifications are possible within the scope and spirit of the present invention, and such alterations and modifications are duly included in the appended claims.

### EXAMPLES AND COMPARATIVE EXAMPLES

Cleaning compositions of the examples and comparative examples were prepared by mixing the components described in Table 1 according to their respective contents. The contents of each component were expressed based on the total weight of the cleaning composition.

TABLE 1

| | (A) | | (B) (wt %) | | | | |
|---|---|---|---|---|---|---|---|
| | A-1 | | B-1 | B-2 | B-3 | B-4 | B-5 |
| Example 1 | 0.1 | ppt | Balance | — | — | — | — |
| Example 2 | 1 | ppt | Balance | — | — | — | — |
| Example 3 | 5 | ppt | Balance | — | — | — | — |
| Example 4 | 10 | ppt | Balance | — | — | — | — |
| Example 5 | 0.5 | ppb | Balance | — | — | — | — |
| Example 6 | 1 | ppb | Balance | — | — | — | — |
| Example 7 | 10 | ppt | 99.99 | Balance | — | — | — |
| Example 8 | 10 | ppt | 99.99 | — | Balance | — | — |
| Example 9 | 10 | ppt | 99.99 | — | — | Balance | — |
| Example 10 | 10 | ppt | 99.99 | — | — | — | Balance |
| Comparative | 2 | ppb | Balance | — | — | — | — |

| | | | | | | |
|---|---|---|---|---|---|---|
| Example 1 | | | | | | |
| Comparative | — | 100 | — | — | — | — |
| Example 2 | | | | | | |

(A) Zeolite
A-1: Zeolite (Sigma-Aldrich; CAS No. 1318-02-1)
(B) Alcohol solvent
B-1: 2-propanol (isopropyl alcohol)
B-2: 1-propanol
B-3: Ethanol
B-4: 1-butanol
B-5: 1-pentanol

### EXPERIMENTAL EXAMPLE

The properties of the cleaning compositions of the examples and comparative examples were evaluated according to the following method, and results thereof are shown in Table 2.

### (1) Initial Evaluation

The total content (Y) of acetaldehyde and acetone included in the cleaning compositions of the examples and comparative examples was measured using Agilent 7890A/5975C GC-MS equipment and an Agilent CP-Volamine (60 m, 0.32 mm) column.

Specifically, standard substances of acetaldehyde and acetone were prepared, then the acetaldehyde and acetone detected as a result of the analysis of the cleaning compositions of the examples and comparative examples were quantitatively analyzed by comparing their peak areas with those of the pre-quantified standard substances.

### (2) Temporal Evaluation

The cleaning compositions of the examples and comparative examples were stored at 60° C. for 90 days, and then the total content (X) of acetaldehyde and acetone was measured in the same manner as in (1) above.

### (3) Evaluation of Temporal Stability

The total content change rate of acetaldehyde and acetone was calculated (using equation (X/Y)−1), and the temporal stability of the cleaning compositions according to the examples and comparative examples was evaluated according to the following evaluation criteria.

### <Evaluation Criteria>:

⊚: Content change rate is 0.1 or less
∘: Content change rate is greater than 0.1 and less than 0.3
Δ: Content change rate is 0.3 or more

### (4) Evaluation of Water Content

The water content of the cleaning compositions according to the examples and comparative examples was measured at room temperature under anhydrous methanol using a moisture meter V20 (manufactured by METTLER TOLEDO) that uses the Karl Fischer measurement method as its measuring principle.

TABLE 2

| | Initial | | | | | | Content | | Water |
|---|---|---|---|---|---|---|---|---|---|
| | evaluation (ppb) | | | Evaluation (ppb) | | | change | Temporal | content |
| | C-1 | C-2 | Total | C-1 | C-2 | Total | rate | stability | (ppm) |
| Example 1 | 1145 | 1042 | 2187 | 1170 | 1069 | 2239 | 0.024 | ⊚ | 15.0 |
| Example 2 | 1142 | 1020 | 2162 | 1177 | 1055 | 2232 | 0.032 | ⊚ | 14.2 |
| Example 3 | 1135 | 1047 | 2182 | 1179 | 1087 | 2266 | 0.038 | ⊚ | 13.7 |
| Example 4 | 1143 | 1037 | 2180 | 1200 | 1092 | 2292 | 0.051 | ⊚ | 12.0 |
| Example 5 | 1141 | 1044 | 2185 | 1223 | 1120 | 2343 | 0.072 | ⊚ | 10.3 |
| Example 6 | 1130 | 1044 | 2174 | 1217 | 1123 | 2340 | 0.076 | ⊚ | 9.2 |
| Example 7 | 1127 | 1032 | 2159 | 1188 | 1090 | 2278 | 0.055 | ⊚ | 12.3 |
| Example 8 | 1130 | 1037 | 2167 | 1190 | 1090 | 2280 | 0.052 | ⊚ | 12.3 |
| Example 9 | 1133 | 1035 | 2168 | 1199 | 1099 | 2298 | 0.060 | ⊚ | 11.9 |
| Example 10 | 1139 | 1044 | 2183 | 1199 | 1105 | 2304 | 0.055 | ⊚ | 12.7 |
| Comparative | 1149 | 1045 | 2194 | 1397 | 1269 | 2666 | 0.215 | Δ | 8.0 |
| Example 1 | | | | | | | | | |
| Comparative | 1135 | 1042 | 2177 | 1767 | 1512 | 3279 | 0.506 | X | 33.2 |
| Example 2 | | | | | | | | | |

In Table 2 above, C-1 represents acetaldehyde and C-2 represents acetone.

Referring to Table 2 above, the cleaning compositions of the examples included zeolite. Thereby, the change rate of aldehyde compound and ketone compound contents did not significantly increase, and the water content range also satisfied a range of 1 ppm to 30 ppm even after the compositions were exposed to high temperatures for a long period of time.

On the other hand, the cleaning compositions of the comparative examples did not include zeolite or did include it in excessive amounts, such that the contents of aldehyde compound and ketone compound increased rapidly, resulting in a significant decrease in temporal stability.

In particular, the composition of Comparative Example 2, which did not include zeolite, contained water in a high content, potentially leading to the formation of watermarks after cleaning and drying.

The contents described above are merely examples of applying the principles of the present invention, and other configurations may be further included without departing from the scope of the present invention.

What is claimed is:

1. A cleaning composition comprising:
an alcohol solvent; and
zeolite,
wherein a content of the zeolite is greater than 0 and equal to or less than 1 part per billion (ppb) based on a total weight of the cleaning composition.

2. The cleaning composition according to claim 1, wherein the content of the zeolite is 0.1 part per trillion (ppt) to 0.5 ppb based on the total weight of the cleaning composition.

3. The cleaning composition according to claim 1, wherein the zeolite comprises type A zeolite, type X zeolite or type Y zeolite.

4. The cleaning composition according to claim 1, wherein a water content in the cleaning composition is 1 part per million (ppm) to 30 ppm based on the total weight of the cleaning composition.

5. The cleaning composition according to claim 1, wherein the alcohol solvent comprises an alcohol having 2 to 5 carbon atoms.

6. The cleaning composition according to claim 1, wherein the alcohol solvent comprises at least one selected from the group consisting of ethanol, 1-propanol, 2-propanol, 1-butanol and 1-pentanol.

7. The cleaning composition according to claim 1, wherein the alcohol solvent comprises 2-propanol and at least one selected from the group consisting of ethanol, 1-propanol, 1-butanol and 1-pentanol.

8. The cleaning composition according to claim 7, wherein a content of 2-propanol, based on the total weight of the cleaning composition, is 99% by weight or more and less than 100% by weight.

9. The cleaning composition according to claim 1, wherein the cleaning composition satisfies Equation 1 below:
$$C \leq ( X / Y ) - 1 \leq D \qquad [ Equation 1 ]$$
wherein X is a total content of aldehyde compound and ketone compound, based on the total weight of the cleaning composition, measured after storing the cleaning composition at 60° C. for 90 days, Y is the total content of aldehyde compound and ketone compound, based on the total weight of the cleaning composition, measured before the storage, C is greater than 0 and 0.05 or less, and D is 0.07 to 0.2.

10. The cleaning composition according to claim 9, wherein, in Equation 1 above, C is 0.03, and D is 0.1.

11. A method of forming a photoresist pattern, the method comprising:
forming a photoresist film on a substrate;
partially removing the photoresist film to form a photoresist pattern; and
cleaning the substrate, on which the photoresist pattern is formed, using the cleaning composition according to claim 1.
